(19) United States
(12) Patent Application Publication
(10) Pub. No.: US 2015/0146382 A1
(43) Pub. Date: May 28, 2015

(54) PACKAGE SUBSTRATE, METHOD OF MANUFACTURING THE SAME, AND POWER MODULE PACKAGE USING PACKAGE SUBSTRATE

(71) Applicant: SAMSUNG ELECTRO-MECHANICS CO., LTD., Suwon-Si (KR)

(72) Inventors: Bum Sik Jang, Suwon-Si (KR); Sung Min Song, Suwon-si (KR)

(73) Assignee: SAMSUNG ELECTRO-MECHANICS CO., LTD., Suwon-Si (KR)

(21) Appl. No.: 14/332,164

(22) Filed: Jul. 15, 2014

(30) Foreign Application Priority Data
Nov. 27, 2013 (KR) 10-2013-0145575

(51) Int. Cl. H05K 7/02; H05K 1/09; H05K 3/10

(52) U.S. Cl. CPC H05K 7/026; H05K 3/10; H05K 1/09
USPC 361/728; 29/846; 174/268

(57) ABSTRACT

Disclosed herein are a package substrate, a method of manufacturing the same, and a power module package using the package substrate. The package substrate includes a substrate including an electronic device adhesive portion formed on one surface thereof and a protrusion portion formed on one side surface of the electronic device adhesive portion, an insulating layer formed on one surface of the substrate, and a circuit pattern formed on the insulating layer, wherein the protrusion portion includes an upper surface portion as a connection member adhesive portion, and a first side surface portion and a second side surface portion that are

### CROSS REFERENCE TO RELATED APPLICATION

This application claims the benefit of Korean Patent Application No. 10-2013-0145575, filed on Nov. 27, 2013, entitled “Package Substrate, Method of Manufacturing the Same, and Power Module Package using Package Substrate”, which is hereby incorporated by reference in its entirety into this application.

### BACKGROUND OF THE INVENTION

1. Technical Field

The present invention relates to a package substrate, a method of manufacturing the same, and a power module package using the package substrate.

2. Description of the Related Art

In general, an inverter board of a home appliance such as a refrigerator, a washing machine, an air conditioner, etc. functions a main role for power control or motor driving.

In particular, a power module package used in the inverter board is a core semiconductor module and an electronic device with high marketability in industrial and automobile fields as well as at home.

A power module package includes a circuit component for power, a control circuit component, a lead frame, a heat radiating plate, and a sealing resin.

With regard to the development of a power module package, the heat radiating characteristics of a substrate are important in terms of module reliability including a lifetime of a power device (insulated gate bipolar transistor (IGBT) or a diode).

Accordingly, in order to improve the heat radiating characteristics of a substrate, a metallic material is used as a base of the substrate, and a structure, obtained via adhesion between a copper (Cu) foil for formation of a metallic base or a circuit and an insulating material or a metallic oxide layer, is used.

### PRIOR ART DOCUMENT

(Patent Document 1) Japanese Patent Laid-Open Publication 2013-21283

### SUMMARY OF THE INVENTION

The present invention has been made in an effort to provide a package substrate, a method of manufacturing the same, and a power module package using the package substrate, for reducing a mounting height of an electronic device to miniaturize the size of a semiconductor package.

The present invention has been made in an effort to provide a package substrate and a method of manufacturing the same, for increasing a space for mounting an electronic device on a substrate to mount a plurality of electronic devices and to enhance a heat radiating effect.

The present invention has been made in an effort to provide a package substrate and a method of manufacturing the same, for preventing sparking adjacent an adhesive portion between a substrate and a lead frame from occurring to damage the substrate.

According to an embodiment of the present invention, there is provided a package substrate including: a substrate including an electronic device adhesive portion formed on one surface thereof and a protrusion portion formed on one side surface of the electronic device adhesive portion, an insulating layer formed on one surface of the substrate, and a circuit pattern formed on the insulating layer, wherein the protrusion portion includes an upper surface portion as a connection member adhesive portion, and a first side surface portion and a second side surface portion that are inclined to converge towards the upper surface portion.

The first side surface portion may be connected to the electronic device adhesive portion.

The electronic device adhesive portion may be lower than a thickness of a cross section of the protrusion portion.

The electronic device adhesive portion may be flat.

An insulating layer may be exposed on the second side surface portion.

The substrate may be formed of a conductive metallic material.

According to another embodiment of the present invention, there is provided a method of manufacturing a package substrate, the method including: forming a cavity on one surface of a substrate, forming an insulating layer on one surface of the substrate, and forming a circuit pattern on the insulating layer, wherein the cavity is formed to form an electronic device adhesive portion and a protrusion portion, and the protrusion portion includes an upper surface portion as a connection member adhesive portion, and a first side surface portion and a second side surface portion that are inclined to converge towards the upper surface portion.

The first side surface portion may be connected to the electronic device adhesive portion.

The electronic device adhesive portion may be lower than a thickness of a cross section of the protrusion portion.

The electronic device adhesive portion may be flat.

The substrate may be formed of a conductive metallic material.

The cavity may be formed using a chemical etching solution.

The forming of the circuit pattern may include exposing the insulating layer on the second side surface portion.

The method may further include forming individual package substrates using a sawing process of separating the electronic device adhesive portion and the second side surface portion, after the forming of the circuit pattern.

According to another embodiment of the present invention, there is provided a power module package including: a package substrate including a substrate including an electronic device adhesive portion and a protrusion portion formed on one surface thereof, an insulating layer formed on one surface of the substrate, and a circuit pattern formed on the insulating layer, the protrusion portion including an upper surface portion as a connection member adhesive portion, and a first side surface portion and a second side surface portion that are inclined to converge towards the upper surface portion, a first lead frame adhered onto a circuit pattern on an upper surface portion of the protrusion portion, a first electronic device mounted on the circuit pattern on the electronic device adhesive portion, a second lead frame facing the first lead frame and spaced apart from the substrate by a predetermined distance, and a second electronic device mounted on the second lead frame.

The first side surface portion may be connected to the electronic device adhesive portion.

The electronic device adhesive portion may be lower than a thickness of a cross section of the protrusion portion.

The electronic device adhesive portion may be flat.

An insulating layer may be exposed on the second side surface portion.

The substrate may be formed of a conductive metallic material.

The power module package may further include a molding portion exposing the other surface of the substrate, and portions of the first lead frame and the second lead frame and covering the remaining portions.

The power module package may further include a wire for electrically connecting the first electronic device, the second electronic device, the first lead frame, and the second lead frame.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a schematic cross-sectional view of a package substrate according to an embodiment of the present invention;

FIGS. 2 to 7 are cross-sectional views sequentially illustrating a method of manufacturing the package substrate according to an embodiment of the present invention; and

FIG. 8 is a schematic cross-sectional view of a power module package according to an embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Package Substrate

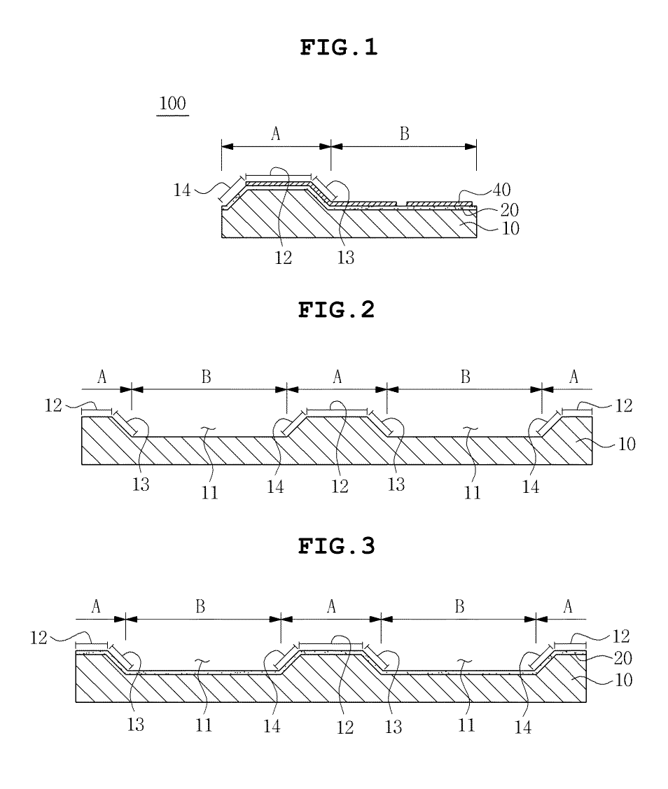

FIG. 1 is a schematic cross-sectional view of a package substrate 100 according to an embodiment of the present invention.

Referring to FIG. 1, the package substrate 100 according to the present embodiment of the present invention includes a substrate 10 including an electronic device adhesive portion B formed on one surface thereof and a protrusion portion A formed on one side surface of the electronic device adhesive portion B, an insulating layer 20 formed on one surface of the substrate 10, and a circuit pattern 40 formed on the insulating layer 20. The protrusion portion A includes an upper surface portion 12 as a connection member adhesive portion, and a first side surface portion 13 and a second side surface portion 14 that are inclined to converge towards the upper surface portion 12.

The substrate 10 may be formed of, for example, a conductive metallic material that is easily obtained and has excellent heat transfer characteristics and may be formed of any one selected from aluminum (Al), an Al alloy, copper (Cu), iron (Fe), iron-nickel (Fe—Ni) alloy, or titanium (Ti).

However, according to the present invention, the material of the substrate 10 is not particularly thereto.

The substrate 10 may be, but is not particularly limited to, a printed circuit board, a ceramic substrate, or a metallic substrate including an anodic oxide layer.

Although not illustrated in FIG. 1, the package substrate 100 according to an embodiment of the present invention may be a metallic substrate including an anodic oxide layer.

The anodic oxide layer is generated by immersing a metallic substrate formed of, for example, Al or an Al alloy in an electrolyte such as boric acid, phosphoric acid, sulfuric acid, chromic acid and then applying a positive pole and a negative pole to the metallic substrate and the electrolyte, respectively. The anodic oxide layer has insulating performance and relatively high heat transfer characteristics of about 10 to 30 W/mk.

As described above, the anodic oxide layer formed of Al or an Al alloy may be an Al anodic oxide (Al₂O₃) layer.

The anodic oxide layer has insulating characteristics and thus allows a circuit layer to be formed on a substrate. In addition, the anodic oxide is formed to a smaller thickness than a general insulating layer 20 and thus may improve heat radiating performance and may also thin the package substrate 100.

The insulating layer 20 may be formed on the electronic device adhesive portion B and the protrusion portion A that correspond to one surface of the substrate 10.

The insulating layer 20 may be formed of thermosetting resin such as epoxy resin, thermoplastic resin such as polyimide, or resin obtained by impregnating these with a stiffener such as a glass fiber or inorganic filler, for example, prepreg, and may also be formed of thermosetting resin and/or photo curable resin, but the present embodiment is not particularly limited thereto.

In addition, the circuit pattern 40 may be further formed on the insulating layer 20.

The circuit pattern 40 may be formed of any conductive metal without limitation. In general, the circuit pattern 40 may be formed of copper (Cu).

The substrate 10 may include the electronic device adhesive portion B formed on one surface thereof and the protrusion portion A formed on one side surface of the electronic device adhesive portion B.

The electronic device adhesive portion B of the substrate 10 may have a lower thickness than a thickness of a cross section of the protrusion portion A, may be flat, and may be formed one side surface of the protrusion portion A.

In this case, the electronic device adhesive portion B is connected to first side surface portion 13 of the protrusion portion A to be described below.

The protrusion portion A of the substrate 10 includes the upper surface portion 12 as a connection member adhesive portion, and the first side surface portion 13 and the second side surface portion 14 that are inclined to converge towards the upper surface portion 12.

The upper surface portion 12 may be a connection member adhesive portion. Package internal and external terminals for electrical connection may be adhered to the upper surface portion 12.

In general, the external connection terminal may be a lead frame and may be any component for electrical connection without limitation.

In this case, as described above, the first side surface portion 13 is an inclined surface connecting the upper surface portion 12 of the protrusion portion A to the electronic device adhesive portion B.

In addition, the second side surface portion 14 facing the first side surface portion 13 is an inclined surface connecting the upper surface portion 12 to one end of the protrusion portion A.

In this case, the circuit pattern 40 is formed on the upper surface portion 12 and the first side surface portion 13. The circuit pattern 40 is not formed on second side surface portion 14 to expose the insulating layer 20.

The exposed second side surface portion 14 protects the package substrate 100 from sparking that may be generated during electrical connection with a connection member adhered onto the circuit pattern 40 of the protrusion portion A of the substrate 10, and thus, may function an important role for ensuring the reliability of the package substrate 100.

The substrate 10 of the package substrate 100 according to an embodiment of the present invention has the electronic device adhesive portion B which has a great length, and thus may ensure a sufficient space for mounting devices. Thus, through the package substrate 100 according to the present invention, a power module package with high density and high integration may be manufactured.

In addition, since the substrate 10 includes the protrusion portion A, a mounting height is reduced compared with a conventional case, and since the substrate 10 with a large volume is used, even if a plurality of power devices is mounted, excellent reliability and heat radiating effect may be achieved.

Method of Manufacturing Package Substrate

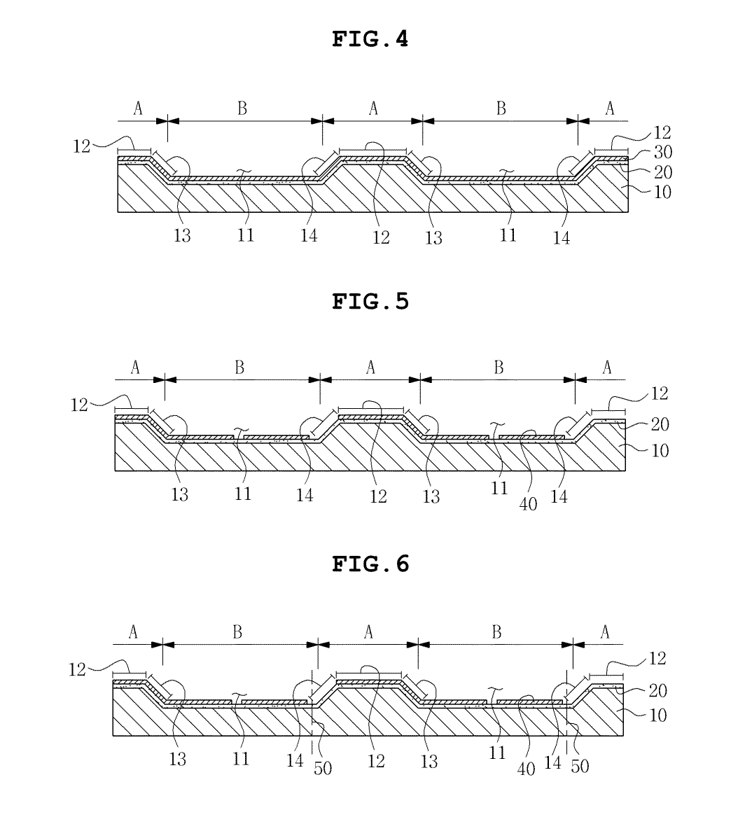

FIGS. 2 to 7 are cross-sectional views sequentially illustrating a method of manufacturing the package substrate 100 according to an embodiment of the present invention.

Referring to FIG. 2, a cavity 11 is formed on one surface of the substrate 10. In this case, the cavity 11 may be formed using a chemical etching solution.

The substrate 10 may be formed of, for example, a conductive metallic material that is easily obtained and has excellent heat transfer characteristics and may be formed of any one selected from aluminum (Al), an Al alloy, copper (Cu), iron (Fe), iron-nickel (Fe—Ni) alloy, or titanium (Ti).

However, according to the present invention, the material of the substrate 10 is not particularly thereto.

The substrate 10 may be, but is not particularly limited to, a printed circuit board, a ceramic substrate, or a metallic substrate including an anodic oxide layer.

Although not illustrated in FIG. 2, the substrate 10 according to an embodiment of the present invention may be a metallic substrate including an anodic oxide layer.

The anodic oxide layer is generated by immersing a metallic substrate formed of, for example, Al or an Al alloy in an electrolyte such as boric acid, phosphoric acid, sulfuric acid, chromic acid and then applying a positive pole and a negative pole to the metallic substrate and the electrolyte, respectively. The anodic oxide layer has insulating performance and relatively high heat transfer characteristics of about 10 to 30 W/mk.

As described above, the anodic oxide layer formed of Al or an Al alloy may be an Al anodic oxide (Al₂O₃) layer.

The anodic oxide layer has insulating characteristics and thus allows a circuit layer to be formed on a substrate. In addition, the anodic oxide is formed to a smaller thickness than a general insulating layer 20 and thus may improve heat radiating performance and may also thin the package substrate 100.

The cavity 11 may be formed on the substrate 10 such that the electronic device adhesive portion B is formed on one surface of the substrate 10 and the protrusion portion A is formed on one side surface of the electronic device adhesive portion B.

The electronic device adhesive portion B of the substrate 10 may have a lower thickness than a thickness of a cross section of the protrusion portion A, may be flat, and may be formed one side surface of the protrusion portion A.

In this case, the electronic device adhesive portion B is connected to first side surface portion 13 of the protrusion portion A to be described below.

The protrusion portion A of the substrate 10 includes the upper surface portion 12 as a connection member adhesive portion, and the first side surface portion 13 and the second side surface portion 14 that are inclined to converge towards the upper surface portion 12.

The upper surface portion 12 may be a connection member adhesive portion. Package internal and external terminals for electrical connection may be adhered to the upper surface portion 12.

In general, the external connection terminal may be a lead frame and may be any component for electrical connection without limitation.

In this case, as described above, the first side surface portion 13 is an inclined surface connecting the upper surface portion 12 of the protrusion portion A to the electronic device adhesive portion B.

In addition, the second side surface portion 14 facing the first side surface portion 13 is an inclined surface connecting the upper surface portion 12 to one end of the protrusion portion A.

In this case, the circuit pattern 40 is formed on the upper surface portion 12 and the first side surface portion 13. The circuit pattern 40 is not formed on second side surface portion 14 to expose the insulating layer 20.

The exposed second side surface portion 14 protects the package substrate 100 from sparking that may be generated during electrical connection with a connection member adhered onto the circuit pattern 40 of the protrusion portion A of the substrate 10, and thus, may function an important role for ensuring the reliability of the substrate 10.

Referring to FIG. 3, the insulating layer 20 is formed on the substrate 10 including the cavity 11 formed thereon.

The insulating layer 20 may be formed of thermosetting resin such as epoxy resin, thermoplastic resin such as polyimide, or resin obtained by impregnating these with a stiffener such as a glass fiber or inorganic filler, for example, prepreg, and may also be formed of thermosetting resin and/or photo curable resin, but the present embodiment is not particularly limited thereto.

Referring to FIGS. 4 and 5, a seed layer and a plating layer 30 are formed.

Although not illustrated in FIGS. 4 and 5, a thin seed layer may be formed on a surface of the insulating layer 20.

The seed layer may be formed via sputtering as a method for increasing adhesion. The sputtering may be a conventionally well known sputtering method. According to sputtering characteristics, the seed layer may be uniformly formed on a surface of the insulating layer 20.

An opening for formation of the circuit pattern 40 may be formed on the seed layer using a plating resist.

In this case, the plating resist may be a dry film pohotoresist and a liquid photosensitive resist material.

A conductive layer 30 may be formed on the surface on which the seed layer and the plating resist are formed via electroless or electro plating.

Then, the plating resist is removed to expose the thin seed layer formed on the surface of the insulating layer 20.

In this case, the exposed portion of the seed layer is removed to form the circuit pattern 40. The exposed portion of the seed layer may be removed via etching, that is, flash etching.

A method of forming the circuit pattern 40 is not limited thereto. That is, a conventional known method of forming a circuit pattern 40 may be used to form the circuit pattern 40.

Referring to FIGS. 6 and 7, a cut portion 50 between the second side surface portion 14 of the protrusion portion A and the electronic device adhesive portion B that has been described with reference to FIG. 1 is cut in a sawing process.

The cut portion 50 is cut to separate the package substrate 100 into individual packages substrates 100 such that the second side surface portion 14 corresponds to an end of the package substrate 100.

In the method of manufacturing the package substrate 100 according to an embodiment of the present invention, the electronic device adhesive portion B for reducing a mounting height for an electronic device on the substrate 10 may be formed using a chemical method, thereby enhancing adhesion with the insulating layer 20 formed on the package substrate 100 and reducing manufacturing costs.

Due to a last operation of separating the package substrate into individual package substrates, easy mass production may be achieved, thereby reducing time and cost.

Power Module Package

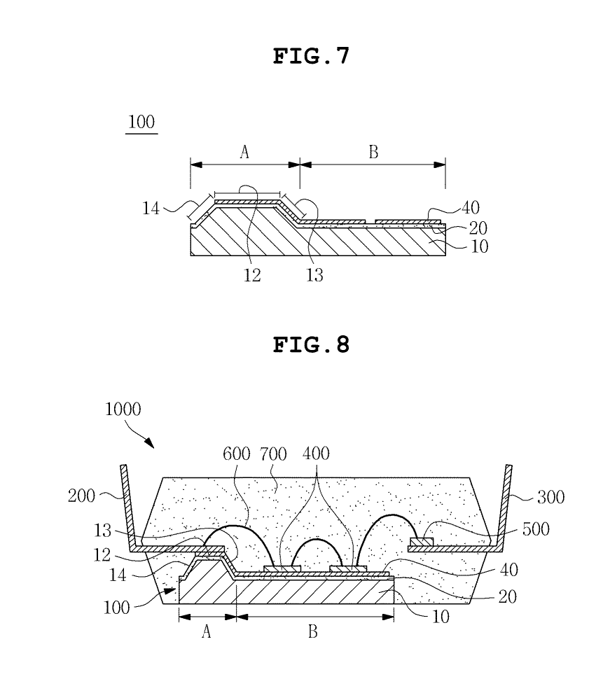

FIG. 8 is a schematic cross-sectional view of a power module package 1000 according to an embodiment of the present invention.

The power module package 1000 according to the present invention includes the substrate 10 with one surface including the electronic device adhesive portion B and the protrusion portion A formed thereon, the insulating layer 20 formed on one surface of the substrate 10, and the circuit pattern 40 formed on the insulating layer 20, and includes the package substrate 100 including the upper surface portion 12 as a connection member adhesive portion of the protrusion portion A, and the first side surface portion 13 and the second side surface portion 14 that are inclined to converge towards the upper surface portion 12, a first lead frame 200 adhered onto the circuit pattern 40 of the upper surface portion 12 of the substrate 10, a first electronic device 400 mounted on the circuit pattern 40 of the electronic device adhesive portion B, a second lead frame 300 facing the first lead frame 200 and spaced apart from the substrate 10 by a predetermined distance, and a second electronic device 500 mounted on the second lead frame 300.

In this case, the substrate 10 may be formed of, for example, a conductive metallic material that is easily obtained and has excellent heat transfer characteristics and may be formed of any one selected from aluminum (Al), an Al alloy, copper (Cu), iron (Fe), iron-nickel (Fe—Ni) alloy, or titanium (Ti).

However, according to the present invention, the material of the substrate 10 is not particularly thereto.

The substrate 10 may be, but is not particularly limited to, a printed circuit board, a ceramic substrate, or a metallic substrate including an anodic oxide layer.

Although not illustrated in FIG. 8, the package substrate 100 according to an embodiment of the present invention may be a metallic substrate including an anodic oxide layer.

The anodic oxide layer is generated by immersing a metallic substrate formed of, for example, Al or an Al alloy in an electrolyte such as boric acid, phosphoric acid, sulfuric acid, chromic acid and then applying a positive pole and a negative pole to the metallic substrate and the electrolyte, respectively. The anodic oxide layer has insulating performance and relatively high heat transfer characteristics of about 10 to 30 W/mk.

As described above, the anodic oxide layer formed of Al or an Al alloy may be an Al anodic oxide (Al₂O₃) layer.

The anodic oxide layer has insulating characteristics and thus allows a circuit layer to be formed on a substrate. In addition, the anodic oxide is formed to a smaller thickness than a general insulating layer 20 and thus may improve heat radiating performance and may also thin the package substrate 100.

The insulating layer 20 may be formed on the electronic device adhesive portion B and the protrusion portion A that correspond to one surface of the substrate 10.

The insulating layer 20 may be formed of thermosetting resin such as epoxy resin, thermoplastic resin such as polyimide, or resin obtained by impregnating these with a stiffener such as a glass fiber or inorganic filler, for example, prepreg, and may also be formed of thermosetting resin and/or photo curable resin, but the present embodiment is not particularly limited thereto.

In addition, the circuit pattern 40 may be further formed on the insulating layer 20.

The circuit pattern 40 may be formed of any conductive metal without limitation. In general, the circuit pattern 40 may be formed of copper (Cu).

The substrate 10 may include the electronic device adhesive portion B formed on one surface thereof and the protrusion portion A formed on one side surface of the electronic device adhesive portion B.

The electronic device adhesive portion B of the substrate 10 may have a lower thickness than a thickness of a cross section of the protrusion portion A, may be flat, and may be formed one side surface of the protrusion portion A.

In this case, the electronic device adhesive portion B is connected to first side surface portion 13 of the protrusion portion A to be described below.

The protrusion portion A of the substrate 10 includes the upper surface portion 12 as a connection member adhesive portion, and the first side surface portion 13 and the second side surface portion 14 that are inclined to converge towards the upper surface portion 12.

The upper surface portion 12 may be a connection member adhesive portion. Package internal and external terminals for electrical connection may be adhered to the upper surface portion 12.

In general, the external connection terminal may be a lead frame and may be any component for electrical connection without limitation.

In this case, as described above, the first side surface portion 13 is an inclined surface connecting the upper surface portion 12 of the protrusion portion A to the electronic device adhesive portion B.

In addition, the second side surface portion 14 facing the first side surface portion 13 is an inclined surface connecting the upper surface portion 12 to one end of the protrusion portion A.

In this case, the circuit pattern 40 is formed on the upper surface portion 12 and the first side surface portion 13. The circuit pattern 40 is not formed on second side surface portion 14 to expose the insulating layer 20.

The exposed second side surface portion 14 protects the package substrate 100 from sparking that may be generated during electrical connection with a connection member adhered onto the circuit pattern 40 of the protrusion portion A of the substrate 10, and thus, may function an important role for ensuring the reliability of the substrate 10.

As not illustrated in FIG. 8, the power module package 1000 according to an embodiment of the present invention may further include a heatsink formed on the other surface of the substrate 10, that is, a portion through which the metallic layer is exposed.

The heatsink may include a plurality of heat radiating pins in order to dissipate heat generated from a semiconductor device in the air.

In addition, the heatsink is not particularly limited. In general, the heatsink may be formed of copper (Cu) or tin (Sn) or may be formed by coating Cu or Sn in order to achieve excellent heat transfer and easily adhesion with the substrate 10.

The first lead frame 200 is adhered onto the circuit pattern 40 formed on the upper surface portion 12 of the protrusion portion A as a connection member adhesive portion of the substrate.

In this case, a portion of the first lead frame 200 is exposed out of a molding portion 700 to be described below.

In this case, the lead frame may be formed of, but is not particularly limited to, any one selected from the group copper (Cu), iron (Fe), or iron-nickel (Fe—Ni) alloy.

The first electronic device 400 is mounted on the circuit pattern 40 of the electronic device adhesive portion B of the substrate 10. One or more electronic device may be adhered and may each be a power device. For example, the electronic device may be a device that generates a large amount of heat, such as a silicon controlled rectifier (SCR), a power transistor, an insulated gate bipolar transistor (IGBT), a metal oxide semiconductor (MOS) transistor, a power commutator, a power regulator, an inverter, a converter, a high power semiconductor chip or diode obtained by combining these.

According to the present embodiment, in FIG. 8, detailed components of an electronic device are omitted and are schematically illustrated. However, it would be understood by those of ordinary skill in the art to apply an unlimited electronic device with any structure known in the art to a power module package.

The second lead frame 300 facing the first lead frame 200 and spaced apart from the substrate 10 by a predetermined distance may be formed of, but is not limited to, any one selected from copper (Cu), iron (Fe), or iron-nickel (Fe—Ni) alloy.

In this case, a portion of the second lead frame 300 is exposed out of the molding portion 700 to be described below.

The second electronic device 500 is mounted on the second lead frame 300.

One or more electronic devices are adhered and are each a control device such as a control integrated circuit (CIC) that generates a small amount of heat.

According to the present embodiment, in FIG. 8, detailed components of an electronic device are omitted and are schematically illustrated. However, it would be understood by those of ordinary skill in the art to apply an unlimited electronic device with any structure known in the art to a power module package.

A power module package according to an embodiment of the present invention includes a wire 600 for electrically connecting the first electronic device 400, the second electronic device 500, the first lead frame 200, and the second lead frame 300 that have been described above.

A wire 600 bonding process may be performed by, but is not particularly limited to, ball bonding, wedge bonding, and stitch bonding that are well known in the art.

Here, the wire 600 may be formed of, but is not particularly limited to, aluminum (Al), gold (Au), copper (Cu), etc. In general, a wire 600 for applying a high rated voltage to an electronic device as a power device may be formed of Al. This is because a thick wire 600 may be used in order to endure a high voltage, and thus, it is more effective to use Al in terms of reduction in costs than a case in which Au or Cu is used.

In addition, the power module package 1000 may further include the molding portion 700 that exposes the other surface of the substrate 10, and portions of the first lead frame 200 and the second lead frame 300 and covers the remaining portions.

Due to the molding portion 700, the long term reliability of the power module package 1000 may be enhanced.

In addition, a heat radiating effect for blocking heat emitted from the electronic device is achieved.

The molding portion 700 may be formed of, but is not limited to, silicon gel, epoxy molded compound (EMC), etc.

In the power module package 1000 according to an embodiment of the present invention, a mounting height for an electronic device on the package substrate 100 is reduced, thereby miniaturizing the power module package 1000.

In addition, a space for mounting an electronic device is increased on the package substrate 100 so as to embody a semiconductor package with high density and high integration.

The length of the package substrate 100 is increased and the protrusion portion A is formed to increase the volume of a metallic substrate, thereby enhancing heat radiating characteristics.

The length and area of the insulating layer 20 for protecting the substrate 10 from sparking are increased to minimize product failure, thereby enhancing reliability.

The substrate 10 is shaped to be easily adhered to a lead frame to reduce the number of processing steps of the lead frame, thereby reducing the number of steps, time, and costs.

A mounting height for an electronic device on the package substrate 100 is reduced and a height of the wire 600 connected between electronic devices and connecting an electronic device and a lead frame is also reduced, thereby reducing the height of the power module package 1000 and miniaturizing the power module package 1000.

A height for the formed molding portion 700 is reduced to miniaturize the size of the power module package 1000 and to reduce material costs.

With regard to the package substrate according to an embodiment of the present invention, a mounting height for an electronic device is reduced to miniaturize a semiconductor package.

A mounting space for an electronic device is increased on a substrate, and thus, a semiconductor package with high density and high integration may be manufactured.

The length of the substrate is increased and the protrusion portion is formed to increase the volume of a metallic substrate, thereby enhancing heat radiating characteristics.

The length and area of the insulating layer for protecting the substrate from sparking are increased to minimize product failure, thereby enhancing reliability.

In a method of manufacturing a package substrate according to an embodiment of the present invention, the electronic device adhesive portion for reducing a mounting height for an electronic device on the substrate may be formed using for reducing a mounting height for an electronic device on the substrate may be formed using a chemical method, thereby enhancing adhesion with the insulating layer formed on the substrate and reducing manufacturing costs.

Due to a last operation of separating the package substrate into individual package substrates, easy mass production may be achieved, thereby reducing time and cost.

In a power module package according to an embodiment of the present invention, a mounting height for an electronic device on the substrate is reduced, thereby miniaturizing the package.

In addition, a space for mounting an electronic device is increased on the substrate so as to embody a package with high density and high integration may be manufactured.

The length of the substrate is increased and the protrusion portion is formed to increase the volume of a metallic substrate, thereby enhancing heat radiating characteristics.

The length and area of the insulating layer for protecting the substrate from sparking are increased to minimize product failure, thereby enhancing reliability.

The substrate is shaped to be easily adhered to a lead frame to reduce the number of processing steps of the lead frame, thereby reducing the number of steps, time, and costs.

A mounting height for an electronic device on the package substrate is reduced and a height of the wire connected between electronic devices and connecting an electronic device and a lead frame is also reduced, thereby reducing the height of the package and miniaturizing the package.

In addition, a height for the formed molding portion is reduced to miniaturize the size of the package and to reduce material costs.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A package substrate comprising:
a substrate including an electronic device adhesive portion formed on one surface thereof and a protrusion portion formed on one side surface of the electronic device adhesive portion;
an insulating layer formed on one surface of the substrate; and
a circuit pattern formed on the insulating layer,
wherein the protrusion portion includes an upper surface portion as a connection member adhesive portion, and a first side surface portion and a second side surface portion that are inclined to converge towards the upper surface portion.

2. The package substrate as set forth in claim 1, wherein the first side surface portion is connected to the electronic device adhesive portion.

3. The package substrate as set forth in claim 1, wherein the electronic device adhesive portion is lower than a thickness of a cross section of the protrusion portion.

4. The package substrate as set forth in claim 1, wherein the electronic device adhesive portion is flat.

5. The package substrate as set forth in claim 1, wherein an insulating layer is exposed on the second side surface portion.

6. The package substrate as set forth in claim 1, wherein the substrate is formed of a conductive metallic material.

7. A method of manufacturing a package substrate, the method comprising:
forming a cavity on one surface of a substrate;
forming an insulating layer on one surface of the substrate; and
forming a circuit pattern on the insulating layer,
wherein:
the cavity is formed to form an electronic device adhesive portion and a protrusion portion; and
the protrusion portion includes an upper surface portion as a connection member adhesive portion, and a first side surface portion and a second side surface portion that are inclined to converge towards the upper surface portion.

8. The method as set forth in claim 7, wherein the first side surface portion is connected to the electronic device adhesive portion.

9. The method as set forth in claim 7, wherein the electronic device adhesive portion is lower than a thickness of a cross section of the protrusion portion.

10. The method as set forth in claim 7, wherein the electronic device adhesive portion is flat.

11. The method as set forth in claim 7, wherein the substrate is formed of a conductive metallic material.

12. The method as set forth in claim 7, wherein the cavity is formed using a chemical etching solution.

13. The method as set forth in claim 7, wherein the forming of the circuit pattern includes exposing the insulating layer on the second side surface portion.

14. The method as set forth in claim 7, further comprising forming individual package substrates using a sawing process of separating the electronic device adhesive portion and the second side surface portion, after the forming of the circuit pattern.

15. A power module package comprising:
a package substrate including a substrate including an electronic device adhesive portion and a protrusion portion formed on one surface thereof, an insulating layer formed on one surface of the substrate, and a circuit pattern formed on the insulating layer, the protrusion portion including an upper surface portion as a connection member adhesive portion, and a first side surface portion and a second side surface portion that are inclined to converge towards the upper surface portion;
a first lead frame adhered onto a circuit pattern on an upper surface portion of the protrusion portion;
a first electronic device mounted on the circuit pattern on the electronic device adhesive portion;
a second lead frame facing the first lead frame and spaced apart from the substrate by a predetermined distance; and
a second electronic device mounted on the second lead frame.

16. The power module package as set forth in claim 15, wherein the first side surface portion is connected to the electronic device adhesive portion.

17. The power module package as set forth in claim 15, wherein the electronic device adhesive portion is lower than a thickness of a cross section of the protrusion portion.

18. The power module package as set forth in claim 15, wherein the electronic device adhesive portion is flat.

19. The power module package as set forth in claim 15, wherein an insulating layer is exposed on the second side surface portion.

20. The power module package as set forth in claim 15, wherein the substrate is formed of a conductive metallic material.

21. The power module package as set forth in claim 15, further comprising a molding portion exposing the other surface of the substrate, and portions of the first lead frame and the second lead frame and covering the remaining portions.

22. The power module package as set forth in claim 15, further comprising a wire for electrically connecting the first electronic device, the second electronic device, the first lead frame, and the second lead frame.
